(19) United States
(12) Patent Application Publication
(10) Pub. No.: US 2023/0213860 A1
(43) Pub. Date: Jul. 6, 2023

(54) POSITIVE-TYPE PHOTOSENSITIVE RESIN COM+POSITION AND CURED FILM PREPARED THEREFROM

(71) Applicant: ROHM AND HAAS ELECTRONIC MATERIALS KOREA LTD., Chungcheongnam-do (KR)

(72) Inventors: Jin Kyu IM, Gyeonggi-do (KR); Ju-Young JUNG, Gyeonggi-do (KR); Eun Sol KIM, Gyeonggi-do (KR); Yeonok KIM, Gyeonggi-do (KR)

(21) Appl. No.: 18/075,357

(22) Filed: Dec. 5, 2022

(30) Foreign Application Priority Data
Dec. 30, 2021 (KR) 10-2021-0193142

(51) Int. Cl. G03F 7/039

(52) U.S. Cl. CPC G03F 7/039

(57) ABSTRACT

The present invention relates to a positive-type photosensitive resin composition and to a cured film prepared therefrom. The positive-type photosensitive resin composition may have excellent storage stability as it comprises an orthoester, and a cured film prepared therefrom may have excellent adhesion and chemical resistance.

### TECHNICAL FIELD

The present invention relates to a positive-type photosensitive resin composition and to a cured film prepared therefrom. Specifically, the present invention relates to a positive-type photosensitive resin composition that is improved in storage stability, adhesion, and chemical resistance and to a cured film prepared therefrom to be used in a liquid crystal display, an organic EL display, and the like.

### BACKGROUND ART

A transparent cured film (planarization film) is formed on a substrate of a thin film transistor (TFT) for the purpose of insulation to prevent a contact between a transparent electrode and a data line in a liquid crystal display, an organic EL display, or the like. The use of such a cured film enhances the aperture ratio of a panel through a transparent pixel electrode positioned near the data line, which makes it possible to attain high luminance/resolution.

Positive-type photosensitive resin compositions capable of forming a specific pattern through relatively fewer steps are used for preparing such a cured film. Specifically, a positive-type photosensitive resin composition that comprises an acrylic resin as a raw material, which can enhance the chemical resistance of a cured film attributable to the crosslinking characteristic of acryl, may be used. However, a cured film formed from such a positive-type photosensitive resin composition has a problem in that the film retention rate is low and the bonding strength to a substrate is weak, so that adhesion is poor.

In order to solve the above problems, a positive-type photosensitive resin composition comprising a siloxane copolymer as a raw material together with an acrylic resin has been proposed (see Patent Document 1). As the siloxane copolymer contains a silanol group to serve as a binder, it is possible to increase the film retention rate of a cured film and to improve its adhesion.

However, a siloxane copolymer forms water during its polymerization or curing process. The water thus formed changes the characteristics of other functional groups to reduce the storage stability of the positive-type photosensitive resin composition or causes a limit in improving the adhesion and chemical resistance of a cured film to a satisfactory level.

### PRIOR ART DOCUMENT

(Patent Document 1) Korean Laid-open Patent Publication No. 2010-0043259

### DISCLOSURE OF INVENTION

### Technical Problem

In order to solve the above-mentioned problems in the art, the present inventors have conducted various studies. As a result, it has been discovered that if water formed during the polymerization of a siloxane copolymer or its curing process is removed (or decomposed), the characteristics of other functional groups are maintained without a change, which increases the storage stability of the positive-type photosensitive resin composition and enhances the adhesion and chemical resistance of a cured film.

Accordingly, the present invention aims to provide a positive-type photosensitive resin composition that is excellent in storage stability and a cured film prepared therefrom and having excellent physical properties such as adhesion, chemical resistance, and the like.

### Solution to Problem

In order to accomplish the above object, the present invention provides a positive-type photosensitive resin composition, which comprises (A) a siloxane copolymer; (B) a 1,2-quinonediazide compound; (C) an epoxy compound; (D) an orthoester; and (E) a solvent.

In addition, the present invention provides a cured film formed from the positive-type photosensitive resin composition.

### Advantageous Effects of Invention

As the positive-type photosensitive resin composition according to the present invention comprises an orthoester that removes (or decomposes) water formed during the polymerization of a siloxane copolymer or its curing process, residual water that affects the storage (preservation) process of the positive-type photosensitive resin composition may be minimized to thereby attain improved storage stability. In addition, since a cured film prepared (formed) from the positive-type photosensitive resin composition according to the present invention has high crosslinking density and chemical stability, it can have excellent adhesion and chemical resistance.

Accordingly, the positive-type photosensitive resin composition according to the present invention can be advantageously used for forming a planarization film for a thin film transistor (TFT) substrate of a liquid crystal display or an organic EL display, a partition of an organic EL display, an interlayer dielectric of a semiconductor device, and the like.

### BEST MODE FOR CARRYING OUT THE INVENTION

The present invention is not limited to those described below. Rather, it can be modified into various forms as long as the gist of the invention is not altered.

Throughout the present specification, when a part is referred to as “comprising” an element, it is understood that other elements may be comprised, rather than other elements are excluded, unless specifically stated otherwise. In addition, all numbers and expressions relating to quantities of components, reaction conditions, and the like used herein may be understood as being modified by the term “about” unless specifically stated otherwise.

Positive-Type Photosensitive Resin Composition

The present invention relates to a positive-type photosensitive resin composition (hereinafter, to be optionally referred to as “photosensitive resin composition”). The photosensitive resin composition comprises (A) a siloxane copolymer; (B) a 1,2-quinonediazide compound, (C) an epoxy compound; (D) an orthoester; and (E) a solvent, which is explained in detail, as follows.

(A) Siloxane Copolymer

The photosensitive resin composition according to the present invention comprises a siloxane copolymer (or polysiloxane) (A).

The siloxane copolymer comprises a structure derived from a condensate of a silane compound and/or a hydrolysate thereof. In such an event, the silane compound or the hydrolysate thereof may be a monofunctional to tetrafunctional silane compound.

As a result, the siloxane copolymer may comprise a siloxane structural unit selected from the following Q, T, D, and M types:
Q type siloxane structural unit: a siloxane structural unit comprising a silicon atom and four adjacent oxygen atoms, which may be derived from, for example, a tetrafunctional silane compound or a hydrolysate of a silane compound that has four hydrolyzable groups.
T type siloxane structural unit: a siloxane structural unit comprising a silicon atom and three adjacent oxygen atoms, which may be derived from, for example, a trifunctional silane compound or a hydrolysate of a silane compound that has three hydrolyzable groups.
D type siloxane structural unit: a siloxane structural unit comprising a silicon atom and two adjacent oxygen atoms (i.e., a linear siloxane structural unit), which may be derived from, for example, a difunctional silane compound or a hydrolysate of a silane compound that has two hydrolyzable groups.
M type siloxane structural unit: a siloxane structural unit comprising a silicon atom and one adjacent oxygen atom, which may be derived from, for example, a monofunctional silane compound or a hydrolysate of a silane compound that has one hydrolyzable group.

Specifically, the siloxane copolymer comprises a structural unit derived from two types of a silane compound represented by the following Formula 2. For example, the siloxane copolymer may be a condensate of two types of a silane compound represented by the following Formula 2 and/or a hydrolysate thereof.

(R³)ₙSi(OR⁴)₄₋ₙ [Formula 2]

In Formula 2, n is an integer of 0 to 3, R³ is each independently a C₁₋₁₂ alkyl group, a C₂₋₁₀ alkenyl group, a C₆₋₁₅ aryl group, a 3- to 12-membered heteroalkyl group, a 4- to 10-membered heteroalkenyl group, or a 6- to 15-membered heteroaryl group; and R⁴ is each independently hydrogen, a C₁₋₆ alkyl group, a C₂₋₆ acyl group, or a C₆₋₁₅ aryl group, wherein the heteroalkyl, the heteroalkenyl, and the heteroaryl groups each independently have at least one heteroatom selected from the group consisting of N, O, and S.

In Formula 2, the compound may be a tetrafunctional silane compound where n is 0, a trifunctional silane compound where n is 1, a difunctional silane compound where n is 2, or a monofunctional silane compound where n is 3.

The silane compound may specifically be, as the tetrafunctional silane compound, tetraacetoxysilane, tetramethoxysilane, tetraethoxysilane, tetrabutoxysilane, tetraphenoxysilane, tetrabenzyloxysilane, or tetrapropoxysilane; as the trifunctional silane compound, methyltrichlorosilane, methyltrimethoxysilane, methyltriethoxysilane, methyltriisopropoxysilane, methyltributoxysilane, ethyltrimethoxysilane, ethyltriethoxysilane, ethyltriisopropoxysilane, ethyltributoxysilane, butyltrimethoxysilane, pentafluorophenyltrimethoxysilane, phenyltrimethoxysilane, phenyltriethoxysilane, d3-methyltrimethoxysilane, nonafluorobutylethyltrimethoxysilane, trifluoromethyltrimethoxysilane, n-propyltrimethoxysilane, n-propyltriethoxysilane, n-butyltriethoxysilane, n-hexyltrimethoxysilane, n-hexyltriethoxysilane, decyltrimethoxysilane, vinyltrimethoxysilane, vinyltriethoxysilane, 3-methacryloxypropyltrimethoxysilane, 3-methacryloxypropyltriethoxysilane, 3-acryloxypropyltrimethoxysilane, 3-acryloxypropyltriethoxysilane, p-hydroxyphenyltrimethoxysilane, 1-(p-hydroxyphenyl)ethyltrimethoxysilane, 2-(p-hydroxyphenyl)ethyltrimethoxysilane, 4-hydroxγ-5-(p-hydroxyphenylcarbonyloxy)pentyltrimethoxysilane, trifluoromethyltriethoxysilane, 3,3,3-trifluoropropyltrimethoxysilane, 3-aminopropyltrimethoxysilane, 3-aminopropyltriethoxysilane, 3-glycidoxypropyltrimethoxysilane, 3-glycidoxypropyltriethoxysilane, 2-(3,4-epoxycyclohexyl)ethyltrimethoxysilane, 2-(3,4-epoxycyclohexyl)ethyltriethoxysilane, [(3-ethyl-3-oxetanyl)methoxy]propyltrimethoxysilane, [(3-ethyl-3-oxetanyl)methoxy]propyltriethoxysilane, 3-mercaptopropyltrimethoxysilane, or 3-trimethoxysilylpropylsuccinic acid; as the difunctional silane compound, dimethyldiacetoxysilane, dimethyldimethoxysilane, diphenyldimethoxysilane, diphenyldiethoxysilane, diphenyldiphenoxysilane, dibutyldimethoxysilane, dimethyldiethoxysilane, (3-glycidoxypropyl)methyldimethoxysilane, (3-glycidoxypropyl)methyldiethoxysilane, 3-(2-aminoethylamino)propyldimethoxymethylsilane, 3-aminopropyldiethoxymethylsilane, 3-chloropropyldimethoxymethylsilane, 3-mercaptopropyldimethoxymethylsilane, cyclohexyldimethoxymethylsilane, diethoxymethylvinylsilane, dimethoxymethylvinylsilane, or dimethoxydi-p-tolylsilane; and as the monofunctional silane compound, trimethylsilane, tributylsilane, trimethylmethoxysilane, tributylethoxysilane, (3-glycidoxypropyl)dimethylmethoxysilane, or (3-glycidoxypropyl)dimethylethoxysilane.

Preferred among the tetrafunctional silane compounds are tetramethoxysilane, tetraethoxysilane, and tetrabutoxysilane; preferred among the trifunctional silane compounds are methyltrimethoxysilane, methyltriethoxysilane, methyltriisopropoxysilane, methyltributoxysilane, phenyltrimethoxysilane, ethyltrimethoxysilane, ethyltriethoxysilane, ethyltriisopropoxysilane, ethyltributoxysilane, and butyltrimethoxysilane; and preferred among the difunctional silane compounds are dimethyldimethoxysilane, diphenyldimethoxysilane, diphenyldiethoxysilane, diphenyldiphenoxysilane, dibutyldimethoxysilane, and dimethyldiethoxysilane.

The conditions for obtaining a hydrolysate of the silane compound of the above Formula 2 or a siloxane copolymer as a condensate thereof are not particularly limited. For example, the silane compound represented by Formula 2 is optionally diluted with a solvent, and water and an acid (e.g., hydrochloric acid, acetic acid, nitric acid, or the like) or a base (e.g., ammonia, triethylamine, cyclohexylamine, tetramethylammonium hydroxide, or the like) as a catalyst are added thereto, followed by stirring the mixture to obtain the desired hydrolysate or a siloxane copolymer as a condensate thereof.

The weight average molecular weight of the siloxane copolymer obtained by the hydrolysis polymerization reaction of the silane compound represented by Formula 2 may be 500 to 50,000, preferably 2,000 to 25,000, more preferably 5,000 to 12,000. Within the above range, it is possible to enhance the film formation characteristics and dissolution rate to a developer.

The types and amounts of the solvent, acid catalyst, and base catalyst are not particularly limited. In addition, the hydrolysis polymerization reaction may be carried out at a low temperature of 20° C. or lower. Alternatively, the reaction may be expedited by heating or refluxing. In addition, the time for the hydrolysis polymerization reaction may be appropriately adjusted according to the type, concentration, reaction temperature, and the like of the silane compound. For example, it usually takes 15 minutes to 30 days for the reaction to be carried out until the molecular weight of the siloxane copolymer thus obtained becomes approximately 500 to 50,000. But it is not limited thereto.

The siloxane copolymer may comprise a linear siloxane structural unit (i.e., D-type siloxane structural unit). This linear siloxane structural unit may be derived from a difunctional silane compound, for example, a compound represented by the above Formula 2 where n is 2. Particularly, the siloxane copolymer may comprise the structural unit derived from the silane compound of the above Formula 2 where n is 2 in an amount of 0.5 to 50% by mole, preferably 1 to 30% by mole, based on the number of moles of Si atoms. Within the above content range, it is possible that a cured film may have flexible characteristics while maintaining a certain level of hardness, whereby the crack resistance to an external stress can be enhanced.

The siloxane copolymer may comprise a structural unit (i.e., siloxane structural unit of T-type) derived from a silane compound represented by the above Formula 2 where n is 1. Particularly, the siloxane copolymer may comprise the structural unit derived from the silane compound of the above Formula 2 where n is 1 in an amount of to 85% by mole, preferably 50 to 80% by mole, based on the number of moles of Si atoms. Within the above content range, it is possible to increase the precision of a pattern formed on a cured film.

The siloxane copolymer may comprise a structural unit derived from a silane compound having an aryl group in view of the hardness, sensitivity, and film retention rate of a cured film. Specifically, the siloxane copolymer may comprise the structural unit derived from a silane compound having an aryl group in an amount of30 to 70% by mole, preferably 35 to 50% by mole, based on the number of moles of Si atoms. Within the above content range, the compatibility of the siloxane copolymer with a 1,2-quinonediazide compound is excellent, which may prevent an excessive decrease in sensitivity while attaining more favorable transparency of a cured film. The structural unit derived from the silane compound having an aryl group may be, for example, a structural unit derived from a silane compound of the above Formula 2 where R³ is an aryl group, preferably a silane compound of the above Formula 2 where n is 1 and R³ is an aryl group, more preferably, a silane compound of the above Formula 2 where n is 1 and R³ is a phenyl group (i.e., siloxane structural unit of T-phenyl type).

The siloxane copolymer may comprise a structural unit (i.e., siloxane structural unit of Q-type) derived from a silane compound represented by the above Formula 2 where n is 0. Specifically, the siloxane copolymer may comprise the structural unit derived from the silane compound of the above Formula 2 where n is 0 in an amount of to 40% by mole, preferably 15 to 35% by mole, based on the number of moles of Si atoms. Within the above content range, the photosensitive resin composition may maintain its solubility to an aqueous alkaline solution at a proper level during the formation of a pattern, thereby preventing any defects caused by a reduction in the solubility or a drastic increase in the solubility of the composition.

The term “% by mole relative to the number of moles of Si atoms” as used herein refers to a percentage of the number of moles of Si atoms contained in a specific structural unit with respect to the total number of moles of Si atoms contained in all of the structural units constituting the siloxane polymer.

The molar content (% by mole) of a siloxane structural unit in the siloxane copolymer may be measured by the combination of Si-NMR, ¹H-NMR, ¹³C-NMR, IR, TOF-MS, elementary analysis, measurement of ash, and the like. For example, in order to measure the molar content of a siloxane structural unit having a phenyl group, an Si-NMR analysis is performed on the entire siloxane copolymer, followed by an analysis of the phenyl-bound Si peak area and the phenyl-unbound Si peak area. The molar amount can then be computed from the peak area ratio between them.

The amount of the siloxane copolymer may be 5% by weight to 80% by weight, 10% by weight to 70% by weight, 15% by weight to 60% by weight, 20% by weight to 50% by weight, 22% by weight to 40% by weight, or 25% by weight to 30% by weight, based on the total weight (total solids content) of the photosensitive resin composition excluding the balanced amount of solvents. Within the above content range, the developability is appropriately controlled, which may enhance the film formation and resolution.

The siloxane copolymer, when pre-cured, may have a dissolution rate of 50 Å/sec or more, preferably, 500 Å/sec or more, more preferably, 1,500 Å or more, in an aqueous solution of 1.5% by weight of tetramethylammonium hydroxide (TMAH). Within the above range, the high developability to a developer may secure excellent resolution. Meanwhile, the upper limit of the dissolution rate is not particularly limited. But it may be 100,000 Å/sec or less, 50,000 Å/sec or less, or 10,000 Å/sec or less.

(B) 1,2-Quinonediazide Compound

The photosensitive resin composition according to the present invention comprises a 1,2-quinonediazide compound (B) as a photoactive agent.

The 1,2-quinonediazide compound may specifically be an ester of a phenolic compound and 1,2-benzoquinonediazide-4-sulfonic acid or 1,2-benzoquinonediazide-5-sulfonic acid; an ester of a phenolic compound and 1,2-naphthoquinonediazide-4-sulfonic acid or 1,2-naphthoquinonediazide-5-sulfonic acid; a sulfonamide of a phenolic compound in which the hydroxyl group is substituted with an amino group and 1,2-benzoquinonediazide-4-sulfonic acid or 1,2-benzoquinonediazide-5-sulfonic acid; or a sulfonamide of a phenolic compound in which the hydroxyl group is substituted with an amino group and 1,2-naphthoquinonediazide-4-sulfonic acid or 1,2-naphthoquinonediazide-5-sulfonic acid. The above compounds may be used alone or in combination of two or more thereof.

The phenolic compound may specifically be 2,3,4-trihydroxybenzophenone, 2,4,6-trihydroxybenzophenone, 2,2′,4,4′-tetrahydroxybenzophenone, 2,3,3′,4-tetrahydroxybenzophenone, 2,3,4,4′-tetrahydroxybenzophenone, bis(2,4-dihydroxyphenyl)methane, bis(p-hydroxyphenyl)methane, tri(p-hydroxyphenyl)methane, 1,1,1-tri(p-hydroxyphenyl)ethane, bis(2,3,4-trihydroxyphenyl)methane, 2,2-bis(2,3,4-trihydroxyphenyl)propane, 1,1,3-tris(2,5-dimethyl-4-hydroxyphenyl)-3-phenylpropane, 4,4′-[1-[4-[1-[4-hydroxyphenyl]-1-methylethyl]phenyl]ethylidene]bisphenol, bis(2,5-dimethyl-4-hydroxyphenyl)-2-hydroxyphenylmethane, 3,3,3′,3′-tetramethyl-1,1′-spirobiindene-5,6,7,5′,6′,7′-hexanol, or 2,2,4-trimethyl-7,2′,4′-trihydroxyflavane.

Such a 1,2-quinonediazide compound may specifically be an ester of 2,3,4-trihydroxybenzophenone and 1,2-naphthoquinonediazide-4-sulfonic acid; an ester of 2,3,4-trihydroxybenzophenone and 1,2-naphthoquinonediazide-5-sulfonic acid; an ester of 4,4′-[1-[4-[1-[4-hydroxyphenyl]-1-methylethyl]phenyl]ethylidene]bisphenol and 1,2-naphthoquinonediazide-4-sulfonic acid; or an ester of4,4′-[1-[4-[1-[4-hydroxyphenyl]-1-methylethyl]phenyl]ethylidene]bisphenol and 1,2-naphthoquinonediazide-5-sulfonic acid. The above compounds may be used alone or in combination of two or more thereof.

The content of the 1,2-quinonediazide compound may be 2 to 50 parts by weight, 3 to 45 parts by weight, 4 to 40 parts by weight, 5 to 30 parts by weight, 6 to 25 parts by weight, or 10 to 23 parts by weight, relative to 100 parts by weight of the siloxane copolymer on the basis of solids content. Within the above content range, a pattern is more readily formed, and it is possible to suppress such defects as a rough surface of a cured film upon the formation thereof and such a pattern shape as scum appearing at the bottom portion of the pattern upon development.

(C) Epoxy Compound

The photosensitive resin composition according to the present invention comprises an epoxy compound (C). The epoxy compound, along with the siloxane copolymer, in the present invention may increase the internal density of the siloxane copolymer (siloxane binder), to thereby enhance the chemical resistance of a cured film formed therefrom.

The epoxy compound may be a homo-oligomer or a hetero-oligomer of an unsaturated monomer containing at least one epoxy group.

The unsaturated monomer containing at least one epoxy group may specifically be glycidyl (meth)acrylate, 4-hydroxybutylacrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, 2-methylallyl glycidyl ether, o-vinylbenzyl glycidyl ether, m-vinylbenzyl glycidyl ether, p-vinylbenzyl glycidyl ether, or a mixture thereof. Preferably, it may be 3,4-epoxycyclohexyl (meth)acrylate or glycidyl methacrylate.

The epoxy compound may be synthesized by any methods commonly known. An example of the commercially available epoxy compound may be GHP24P(3,4-epoxycyclohexyl (meth)acrylate homopolymer, Miwon Commercial Co., Ltd.).

The epoxy compound may further comprise the following structural unit. Specifically, the additional structural unit may be a structural unit derived from a compound such as styrene; styrene containing an alkyl substituent such as methylstyrene, dimethylstyrene, trimethylstyrene, ethylstyrene, diethylstyrene, triethylstyrene, propylstyrene, butylstyrene, hexylstyrene, heptylstyrene, and octylstyrene; styrene containing a halogen such as fluorostyrene, chlorostyrene, bromostyrene, and iodostyrene; styrene containing an alkoxy substituent such as methoxystyrene, ethoxystyrene, and propoxystyrene; p-hydroxγ-α-methylstyrene; acetylstyrene; an ethylenically unsaturated compound containing an aromatic ring such as divinylbenzene, vinylphenol, o-vinylbenzyl methyl ether, m-vinylbenzyl methyl ether, p-vinylbenzyl methyl ether; an unsaturated carboxylic acid ester such as methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxγ-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, phenyl (meth)acrylate, benzyl (meth)acrylate, 2-phenoxyethyl (meth)acrylate, phenoxydiethylene glycol (meth)acrylate, p-nonylphenoxy polyethylene glycol (meth)acrylate, p-nonylphenoxy polypropylene glycol (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, tribromophenyl (meth)acrylate, isobornyl (meth)acrylate, dicyclopentanyl (meth)acrylate, dicyclopentenyl (meth)acrylate, dicyclopentanyloxyethyl (meth)acrylate, and dicyclopentenyloxyethyl (meth)acrylate; a tertiary amine containing an N-vinyl group such as N-vinyl pyrrolidone, N-vinyl carbazole, and N-vinyl morpholine; or an unsaturated ether such as vinyl methyl ether and vinyl ethyl ether; an unsaturated imide such as N-phenylmaleimide, N-(4-chlorophenyl)maleimide, N-(4-hydroxyphenyl)maleimide, and N-cyclohexylmaleimide.

The structural unit derived from the above compounds may be contained in the epoxy compound alone or in combination of two or more thereof. Preferably, a structural unit derived from the styrene compounds among the above is preferred from the viewpoint of polymerizability. In particular, it may be more preferable in terms of the chemical resistance that the epoxy compound does not contain a carboxyl group by way of not comprising a structural unit derived from a monomer containing a carboxyl group among the compounds exemplified above.

The epoxy compound may comprise the above structural unit in an amount of 0 to 70% by mole, preferably 10 to 60% by mole, based on the total number of moles of the structural units constituting the epoxy compound. Within the above content range, it may be more advantageous in terms of the film strength.

The weight average molecular weight of the epoxy compound may be 100 to 30,000, preferably, 1,000 to 15,000, more preferably, 3,000 to 10,000. Within the above range, a cured film may have more excellent hardness with a uniform thickness, which may be suitable for planarizing any steps.

The content of the epoxy compound may be 0.2 to 40 parts by weight, 0.3 to 38 parts by weight, 0.5 to 35 parts by weight, 1 to 30 parts by weight, 5 to 25 parts by weight, or 10 to 20 parts by weight, relative to 100 parts by weight of the siloxane copolymer on the basis of solids content. Within the above content range, the chemical resistance and adhesion of a cured film may be enhanced.

(D) Orthoester

The photosensitive resin composition according to the present invention comprises an orthoester (D). The orthoester, along with the siloxane copolymer and the epoxy compound, in the present invention decomposes (removes) water generated during the polymerization or curing of the siloxane copolymer, to thereby prevent the deterioration in the storage stability of the photosensitive resin composition due to residual water. In addition, it is possible to prevent a ring-opening reaction of the epoxy compound induced by water, which may otherwise cause the crosslinking density between the siloxane copolymer and the epoxy compound to be reduced; thus, it is possible to improve the adhesion and chemical resistance of a cured film.

Specifically, the siloxane copolymer generates water in the polymerization process as shown in the following Reaction Scheme 1, which remains in the photosensitive resin composition together with the catalyst (e.g., acid catalyst) used in the polymerization process to induce an addition reaction, so that storage stability of the photosensitive resin composition may be deteriorated.

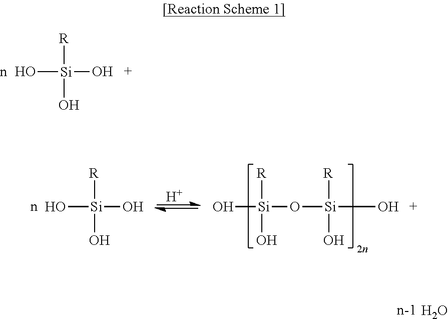

In contrast, the orthoester in the present invention decomposes (removes) water generated during the polymerization or curing of the siloxane copolymer, thereby improving the deterioration in the storage stability of the photosensitive resin composition and the deterioration in the adhesion and chemical resistance of a cured film due to residual water. That is, the orthoester according to the present invention may be a compound represented by the following Formula 1, which may react with water generated in the polymerization or curing process of the siloxane copolymer as shown in the following Reaction Scheme 2 to decompose water into alcohol-based compounds and ketone-based compounds having low latent heat. If water is decomposed into alcohol-based compounds and ketone-based compounds having low latent heat, the loss of energy required for the crosslinking reaction is prevented, thereby increasing the crosslinking density of a cured film. As a result, the chemical resistance of a cured film can be enhanced.

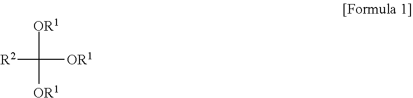

In Formula 1, R¹ is each independently a substituted or unsubstituted C₁₋₁₀ alkyl group, and R² is hydrogen or a substituted or unsubstituted C₁₋₁₀ alkyl group.

When the alkyl groups of R¹ and R² are substituted, the substituent may be a C₁₋₅ alkyl group.

Specifically, R¹ may be a substituted or unsubstituted methyl group, ethyl group, propyl group, or butyl group, and R² may be hydrogen, a methyl group, or an ethyl group.

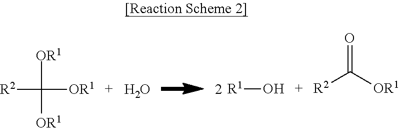

The orthoester may specifically be at least one selected from the group consisting of methyl orthoformate, ethyl orthoformate, propyl orthoformate, methyl orthoacetate, ethyl orthoacetate, and propyl orthoacetate.

The content of the orthoester may be 1 to 800 parts by weight, 5 to 750 parts by weight, 10 to 700 parts by weight, 20 to 650 parts by weight, 30 to 600 parts by weight, 40 to 550 parts by weight, 50 to 520 parts by weight, 60 to 500 parts by weight, or 70 to 460 parts by weight, relative to 100 parts by weight of the siloxane copolymer on the basis of solids content. Within the above content range, the chemical resistance and adhesion of a cured film may be enhanced while the storage stability of the photosensitive resin composition is secured.

(E) Solvent

The photosensitive resin composition according to the present invention comprises a solvent (E). The solvent (E) serves to dissolve or disperse each component contained in the photosensitive resin composition.

The solvent is not particularly limited as long as it can dissolve the above-mentioned components and is chemically stable. Specifically, the solvent may be an organic solvent such as alcohols, ethers, glycol ethers, ethylene glycol alkyl ether acetates, diethylene glycol, propylene glycol monoalkyl ethers, propylene glycol alkyl ether acetates, propylene glycol alkyl ether propionates, aromatic hydrocarbons, ketones, or esters.

More specifically, the solvent may be methanol, ethanol, tetrahydrofuran, dioxane, methyl cellosolve acetate, ethyl cellosolve acetate, ethyl acetoacetate, ethylene glycol monomethyl ether, ethylene glycol monoethyl ether, ethylene glycol dimethyl ether, ethylene glycol diethyl ether, propylene glycol dimethyl ether, propylene glycol diethyl ether, diethylene glycol monomethyl ether, diethylene glycol monoethyl ether, diethylene glycol dimethyl ether, diethylene glycol ethyl methyl ether, propylene glycol monomethyl ether, propylene glycol monoethyl ether, propylene glycol monopropyl ether, dipropylene glycol dimethyl ether, dipropylene glycol diethyl ether, propylene glycol monomethyl ether acetate, propylene glycol monoethyl ether acetate, propylene glycol monopropyl ether acetate, dipropylene glycol methyl ether acetate, propylene glycol butyl ether acetate, toluene, xylene, methyl ethyl ketone, 4-hydroxγ-4-methyl-2-pentanone, cyclopentanone, cyclohexanone, 2-heptanone, γ-butyrolactone, ethyl 2-hydroxypropionate, ethyl 2-hydroxγ-2-methylpropionate, ethyl ethoxyacetate, ethyl hydroxyacetate, methyl 2-hydroxγ-3-methylbutanoate, methyl 2-methoxypropionate, methyl 3-methoxypropionate, ethyl 3-methoxypropionate, ethyl 3-ethoxypropionate, methyl 3-ethoxypropionate, methyl pyruvate, ethyl pyruvate, ethyl acetate, butyl acetate, ethyl lactate, butyl lactate, N,N-dimethylformamide, N,N-dimethylacetamide, or N-methylpyrrolidone. The above compounds may be used alone or in combination of two or more thereof.

Preferred among the above are ethylene glycol alkyl ether acetates, diethylene glycols, propylene glycol monoalkyl ethers, propylene glycol monoalkyl ether acetates, ketones, and the like. In particular, preferred are diethylene glycol dimethyl ether, diethylene glycol ethyl methyl ether, dipropylene glycol dimethyl ether, dipropylene glycol diethyl ether, propylene glycol monomethyl ether, propylene glycol monoethyl ether, propylene glycol monomethyl ether acetate, methyl 2-methoxypropionate, γ-butyrolactone, 4-hydroxγ-4-methyl-2-pentanone, and the like.

The content of the solvent is not particularly limited, but it may be the balanced amount excluding the solids content based on the total weight of the photosensitive resin composition. Specifically, the content of the solvent may be adjusted such that the solids content is 10 to 70% by weight, 15 to 65% by weight, 20 to 60% by weight, or 25 to 55% by weight, based on the total weight of the photosensitive resin composition.

(F) Acrylic Copolymer

The photosensitive resin composition according to the present invention may further comprise an acrylic copolymer (F). The acrylic copolymer may serve as an alkali-soluble resin for achieving developability in the development step In addition, it may play the role of a base for forming a cured film upon coating and a structure for forming a final pattern.

The acrylic copolymer may comprise (F-1) a structural unit derived from an ethylenically unsaturated carboxylic acid, an ethylenically unsaturated carboxylic anhydride, or a combination thereof; (F-2) a structural unit derived from an unsaturated compound containing an epoxy group; and (F-3) a structural unit derived from an ethylenically unsaturated compound different from the structural units (F-1) and (F-2).

(F-1) Structural Unit Derived from an Ethylenically Unsaturated Carboxylic Acid. An Ethylenically Unsaturated Carboxylic Anhydride, or a Combination Thereof

The structural unit (F-1) is derived from an ethylenically unsaturated carboxylic acid, an ethylenically unsaturated carboxylic anhydride, or a combination thereof. The ethylenically unsaturated carboxylic acid and the ethylenically unsaturated carboxylic anhydride may be a polymerizable unsaturated compound containing at least one carboxyl group in the molecule.

Specifically, the ethylenically unsaturated carboxylic acid, the ethylenically unsaturated carboxylic anhydride, or a combination thereof may be at least one selected from the group consisting of an unsaturated monocarboxylic acid such as (meth)acrylic acid, crotonic acid, alpha-chloroacrylic acid, and cinnamic acid; an unsaturated dicarboxylic acid and an anhydride thereof such as maleic acid, maleic anhydride, fumaric acid, itaconic acid, itaconic anhydride, citraconic acid, citraconic anhydride, and mesaconic acid; an unsaturated polycarboxylic acid having three or more valences and an anhydride thereof; and a mono[(meth)acryloyloxyalkyl] ester of a polycarboxylic acid of divalence or more such as mono[2-(meth)acryloyloxyethyl] succinate, mono[2-(meth)acryloyloxyethyl] phthalate. (Meth)acrylic acid among the above may be preferable from the viewpoint of developability.

The amount of the structural unit (F-1) may be 5 to 50% by mole, preferably 10 to 40% by mole, based on the total moles of the structural units constituting the acrylic copolymer. Within the above range, it is possible to attain a pattern of a cured film with good developability.

(F-2) Structural Unit Derived from an Unsaturated Compound Containing an Epoxy Group

The structural unit (F-2) is derived from an unsaturated monomer containing at least one epoxy group. The unsaturated monomer containing at least one epoxy group may be at least one selected from the group consisting of glycidyl (meth)acrylate, 4-hydroxybutyl acrylate glycidyl ether, 3,4-epoxybutyl (meth)acrylate, 4,5-epoxypentyl (meth)acrylate, 5,6-epoxyhexyl (meth)acrylate, 6,7-epoxyheptyl (meth)acrylate, 2,3-epoxycyclopentyl (meth)acrylate, 3,4-epoxycyclohexyl (meth)acrylate, α-ethyl glycidyl acrylate, α-n-propyl glycidyl acrylate, α-n-butyl glycidyl acrylate, N-(4-(2,3-epoxypropoxy)-3,5-dimethylbenzyl)acrylamide, N-(4-(2,3-epoxypropoxy)-3,5-dimethylphenylpropyl)acrylamide, allyl glycidyl ether, and 2-methylallyl glycidyl ether. Glycidyl (meth)acrylate, 3,4-epoxycyclohexyl (meth)acrylate, 4-hydroxybutyl acrylate glycidyl ether, or a mixture thereof may be preferable from the viewpoint of storage stability at room temperature and solubility.

The amount of the structural unit (F-2) may be 1 to 45% by mole, preferably 3 to 30% by mole, based on the total moles of the structural units constituting the acrylic copolymer. Within the above content range, the storage stability of the photosensitive resin composition may be maintained, and it may be advantageous for enhancing the film retention rate upon post-bake.

(F-3) Structural Unit Derived from an Ethylenically Unsaturated Compound Different from the Structural Units (F-1) and (F-2)

The structural unit (F-3) is derived from an ethylenically unsaturated compound different from the structural units (F-1) and (F-2). The ethylenically unsaturated compound different from the structural units (F-1) and (F-2) may be specifically at least one selected from the group consisting of an ethylenically unsaturated compound having an aromatic ring including phenyl (meth)acrylate, benzyl (meth)acrylate, 2-phenoxyethyl (meth)acrylate, phenoxy diethylene glycol (meth)acrylate, p-nonylphenoxy polyethylene glycol (meth)acrylate, p-nonylphenoxy polypropylene glycol (meth)acrylate, tribromophenyl (meth)acrylate, styrene, methylstyrene, dimethylstyrene, trimethylstyrene, ethylstyrene, diethylstyrene, triethylstyrene, propylstyrene, butylstyrene, hexylstyrene, heptylstyrene, octylstyrene, fluorostyrene, chlorostyrene, bromostyrene, iodostyrene, methoxystyrene, ethoxystyrene, propoxystyrene, acetylstyrene, vinyl toluene, divinylbenzene, vinylphenol, o-vinylbenzyl methyl ether, m-vinylbenzyl methyl ether, or p-vinylbenzyl methyl ether; an unsaturated carboxylic acid ester including methyl (meth)acrylate, ethyl (meth)acrylate, butyl (meth)acrylate, dimethylaminoethyl (meth)acrylate, isobutyl (meth)acrylate, t-butyl (meth)acrylate, cyclohexyl (meth)acrylate, ethylhexyl (meth)acrylate, tetrahydrofurfuryl (meth)acrylate, hydroxyethyl (meth)acrylate, 2-hydroxypropyl (meth)acrylate, 2-hydroxγ-3-chloropropyl (meth)acrylate, 4-hydroxybutyl (meth)acrylate, glycerol (meth)acrylate, methyl α-hydroxymethylacrylate, ethyl α-hydroxymethylacrylate, propyl α-hydroxymethylacrylate, butyl α-hydroxymethylacrylate, 2-methoxyethyl (meth)acrylate, 3-methoxybutyl (meth)acrylate, ethoxy diethylene glycol (meth)acrylate, methoxy triethylene glycol (meth)acrylate, methoxy tripropylene glycol (meth)acrylate, poly(ethylene glycol) methyl ether (meth)acrylate, tetrafluoropropyl (meth)acrylate, 1,1,1,3,3,3-hexafluoroisopropyl (meth)acrylate, octafluoropentyl (meth)acrylate, heptadecafluorodecyl (meth)acrylate, isobornyl (meth)acrylate, dicyclopentanyl (meth)acrylate, dicyclopentenyl (meth)acrylate, dicyclopentanyloxyethyl (meth)acrylate, dicyclopentenyloxyethyl (meth)acrylate, glycidyl (meth)acrylate, 3,4-epoxybutyl (meth)acrylate, 4,5-epoxypentyl (meth)acrylate, 5,6-epoxyhexyl (meth)acrylate, or 6,7-epoxyheptyl (meth)acrylate; an N-vinyl tertiary amine containing an N-vinyl group including N-vinyl pyrrolidone, N-vinyl carbazole, or N-vinyl morpholine; an unsaturated ether including vinyl methyl ether or vinyl ethyl ether; and an unsaturated imide including N-phenylmaleimide, N-(4-chlorophenyl)maleimide, N-(4-hydroxyphenyl)maleimide, or N-cyclohexylmaleimide.

The amount of the structural unit (F-3) may be 5 to 70% by mole, preferably 15 to 65% by mole, based on the total moles of the structural units constituting the acrylic copolymer. Within the above range, it is possible to control the reactivity of the acrylic copolymer and to increase the solubility thereof in an aqueous alkaline solution, so that the coatability of the photosensitive resin composition can be enhanced.

The acrylic copolymer may be prepared by compounding each of the compounds that provide the structural units (F-1), (F-2), and (F-3), and adding thereto a molecular weight controlling agent, a polymerization initiator, a solvent, and the like, followed by charging nitrogen thereto and slowly stirring the mixture for carrying out the polymerization.

The molecular weight controlling agent may be a mercaptan compound such as butyl mercaptan, octyl mercaptan, lauryl mercaptan, or the like, or an α-methylstyrene dimer, but it is not particularly limited thereto.

The polymerization initiator may be an azo compound such as 2,2′-azobisisobutyronitrile, 2,2′-azobis(2,4-dimethylvaleronitrile), and 2,2′-azobis(4-methoxγ-2,4-dimethylvaleronitrile); or benzoyl peroxide; lauryl peroxide; t-butyl peroxypivalate; 1,1-bis(t-butylperoxy)cyclohexane, or the like, but it is not limited thereto. The polymerization initiator may be used alone or in combination of two or more thereof.

The solvent may be any solvent commonly used in the preparation of an acrylic copolymer. It may preferably be methyl 3-methoxypropionate or propylene glycol monomethyl ether acetate.

The reaction conditions and the reaction time at the time of preparation of the acrylic copolymer are not particularly limited. For example, the reaction temperature may be adjusted to a temperature lower than the conventional temperature, for example, from room temperature to 70° C. (or to 65° C.). Then, the reaction time is to be preferably maintained until a sufficient reaction is carried out.

It is possible to control the residual amount of unreacted monomers in the acrylic copolymer to a very minute level when the acrylic copolymer is prepared by the above process. The unreacted monomers (or residual monomers) may refer to monomers (compounds) that were supposed to provide the structural units (F-1) to (F-3) of the acrylic copolymer, but have not participated in the polymerization reaction (i.e., do not form a chain of the copolymer).

The weight average molecular weight of the acrylic copolymer may be 500 to 50,000, preferably, 3,000 to 30,000, more preferably, 5,000 to 15,000. Within the above range, the adhesion to a substrate may be excellent, along with an appropriate viscosity.

The content of the acrylic copolymer may be 10 to 700 parts by weight, 25 to 600 parts by weight, 45 to 500 parts by weight, 60 to 400 parts by weight, 75 to 300 parts by weight, or 100 to 250 parts by weight, relative to 100 parts by weight of the siloxane copolymer on the basis of solids content. Within the above content range, the developability and film retention rate may be excellent.

Meanwhile, as used herein, the term “(meth)acryl” may refer to “acryl” and/or “methacryl,” and the term “(meth)acrylate” refers to “acrylate” and/or “methacrylate.”

The photosensitive resin composition according to the present invention may further comprise additives such as surfactants, adhesion aids, defoamers, viscosity modifiers, dispersants, or the like.

The surfactant may enhance the coatability of the photosensitive resin composition. The surfactant is not particularly limited, but examples thereof include fluorine-based surfactants, silicone-based surfactants, non-ionic surfactants, and the like.

The surfactant may specifically be fluorine- and silicon-based surfactants such as FZ-2122 supplied by Dow Corning Toray Co., Ltd., BM-1000 and BM-1100 supplied by BM CHEMIE Co., Ltd., Megapack F-142 D, F-172, F-173, and F-183 supplied by Dai Nippon Ink Chemical Kogyo Co., Ltd., Florad FC-135, FC-170 C, FC-430, and FC-431 supplied by Sumitomo 3M Ltd., Sufron S-112, S-113, S-131, S-141, S-145, S-382, SC-101, SC-102, SC-103, SC-104, SC-105, and SC-106 supplied by Asahi Glass Co., Ltd., Eftop EF301, EF303, and EF352 supplied by Shinakida Kasei Co., Ltd., SH-28 PA, SH-190, SH-193, SZ-6032, SF-8428, DC-57, and DC-190 supplied by Toray Silicon Co., Ltd.; non-ionic surfactants such as polyoxyethylene alkyl ethers including polyoxyethylene lauryl ether, polyoxyethylene stearyl ether, polyoxyethylene oleyl ether, and the like; polyoxyethylene aryl ethers including polyoxyethylene octylphenyl ether, polyoxyethylene nonylphenyl ether, and the like; and polyoxyethylene dialkyl esters including polyoxyethylene dilaurate, polyoxyethylene distearate, and the like; or organosiloxane polymer KP341 (manufactured by Shin-Etsu Chemical Co., Ltd.), (meth)acrylate-based copolymer Polyflow Nos. 57 and 95 (manufactured by Kyoei Yuji Chemical Co., Ltd.), and the like. The above compounds may be used alone or in combination of two or more thereof.

The content of the surfactant may be 0.01 to 5 parts by weight, 0.02 to 4 parts by weight, 0.05 to 3 parts by weight, 0.1 to 2 parts by weight, 0.3 to 1.5 parts by weight, or 0.5 to 1 part by weight, relative to 100 parts by weight of the siloxane copolymer on the basis of solids content. Within the above content range, the photosensitive resin composition may have excellent coatability.

The adhesion aid may enhance the adhesion of a cured film prepared (formed) from the photosensitive resin composition. The adhesion aid is not particularly limited, but it may be a compound having at least one reactive group selected from the group consisting of a carboxyl group, a (meth)acryloyl group, an isocyanate group, an amino group, a mercapto group, a vinyl group, and an epoxy group.

Specifically, the adhesion aid may be at least one selected from the group consisting of trimethoxysilyl benzoic acid, γ-methacryloxypropyltrimethoxysilane, vinyltriacetoxysilane, vinyltrimethoxysilane, γ-isocyanatopropyltriethoxysilane, γ-glycidoxypropyltrimethoxysilane, γ-glycidoxypropyltriethoxysilane, N-phenylaminopropyltrimethoxysilane, and β-(3,4-epoxycyclohexyl)ethyltrimethoxysilane. Preferred as the adhesion aid is γ-glycidoxypropyltriethoxysilane, γ-glycidoxypropyltrimethoxysilane, or N-phenylaminopropyltrimethoxysilane from the viewpoint of film retention rate and adhesion.

The content of the adhesion aid may be 0 to 5 parts by weight, 0.001 to 4 parts by weight, 0.005 to 3 parts by weight, or 0.01 to 2 parts by weight, relative to 100 parts by weight of the siloxane copolymer on the basis of solids content. Within the above content range, the adhesion to a substrate may be further enhanced.

Cured Film

The present invention provides a cured film formed from the photosensitive resin composition described above.

The cured film according to the present invention may be formed by a method commonly known, for example, a method in which the photosensitive resin composition is coated onto a substrate and then cured. Specifically, the photosensitive resin composition is coated onto a substrate and subjected to pre-bake at a temperature of 60 to 130° C., preferably 80 to 120° C., to remove solvents; then exposed to light using a photomask having a desired pattern; and subjected to development using a developer (for example, a tetramethylammonium hydroxide (TMAH) solution) to form a pre-baked film having a pattern formed thereon. Thereafter, if necessary, the pre-baked film having a pattern is subjected to post-bake at a temperature of 150 to 300° C., preferably 200 to 250° C., for 10 minutes to 5 hours to prepare a desired cured film.

The exposure to light may be carried out at an exposure dose of 10 to 200 mJ/cm² based on a wavelength of 365 nm in a wavelength band of 200 to 500 nm. In addition, as a light source used for the exposure, a low-pressure mercury lamp, a high-pressure mercury lamp, an extra high-pressure mercury lamp, a metal halide lamp, an argon gas laser, or the like may be used. X-rays, electronic rays, or the like may also be used, if desired.

The method of coating the photosensitive resin composition onto a substrate may be a spin coating, a slit coating, a roll coating, a screen printing, an applicator, or the like. A coating film in a desired thickness of, for example, 2 to 25 μm may be prepared by this method.

Since the present invention forms a cured film using the photosensitive resin composition described above, it is possible to provide a cured film that is excellent in thermal resistance, transparency, dielectric constant, and solvent resistance, as well as chemical resistance and adhesion. In particular, the cured film of the present invention has excellent chemical resistance and high light transmittance even when it is subjected to thermal treatment or is immersed in, or comes into contact with a solvent, an acid, a base, or the like. Thus, it can be effectively used as a material for a planarization film for a thin film transistor (TFT) substrate of a liquid crystal display or an organic EL display; a partition of an organic EL display; an interlayer dielectric of a semiconductor device; or an optical waveguide. Further, the cured film according to the present invention may be applied as a protective film in electronic components.

### Mode for the Invention

Hereinafter, the present invention will be described in more detail with reference to the following examples. However, these examples are provided to illustrate the present invention, and the scope of the present invention is not limited thereto only.

In the following synthesis examples, the weight average molecular weight is determined by gel permeation chromatography (GPC, eluent: tetrahydrofuran) referenced to a polystyrene standard.

### [Synthesis Example 1] Preparation of a Siloxane Copolymer (A)

A reactor equipped with a reflux condenser was charged with 40.1 parts by weight of phenyltrimethoxysilane, 13.8 parts by weight of methyltrimethoxysilane, 21 parts by weight of tetraethoxysilane, 20 parts by weight of distilled water, and 5 parts by weight of propylene glycol monomethyl ether acetate (PGMEA), followed by refluxing and vigorously stirring the mixture for 6 hours in the presence of 0.1 part by weight of a phosphoric acid catalyst. Then, the mixture was cooled and diluted with PGMEA such that the solids content was 41%. As a result, a siloxane copolymer having a weight average molecular weight of about 6,000 to 9,000 Da was obtained.

### [Synthesis Example 2] Preparation of an Epoxy Compound (C)

A three-necked flask equipped with a cooling tube was placed on a stirrer equipped with a thermostat. Then, the three-necked flask was charged with 100 parts by weight of a monomer composed of 100% by mole of 3,4-epoxycyclohexylmethylmethacrylate, 10 parts by weight of 2,2′-azobis(2-methylbutyronitrile), and 100 parts by weight of propylene glycol monomethyl ether acetate (PGMEA), followed by charging nitrogen thereto. Thereafter, the temperature of the solution was raised to 80° C. while the solution was slowly stirred, and the temperature was maintained for 5 hours to carry out the reaction. Next, the resultant was diluted with PGMEA such that the solids content was 21% by weight. As a result, an epoxy compound having a weight average molecular weight of about 5,000 to 8,000 Da was obtained.

### [Synthesis Example 3] Preparation of an Acrylic Copolymer (F)

A flask equipped with a cooling tube and a stirrer was charged with 200 parts by weight of propylene glycol monomethyl ether acetate (PGMEA) as a solvent, and the temperature of the solvent was raised to 70° C. while the solvent was stirred slowly. Next, added thereto were 43.6 parts by weight of styrene, 17.2 parts by weight of methyl methacrylate, 12.4 parts by weight of glycidyl methacrylate, and 26.8 parts by weight of methacrylic acid, followed by dropwise addition of 3 parts by weight of 2,2′-azobis(2,4-dimethylvaleronitrile) as a radical polymerization initiator over 5 hours to carry out the polymerization reaction. Next, the resultant was diluted with PGMEA such that the solids content was 31% by weight. As a result, an acrylic copolymer having a weight average molecular weight of about 5,000 to 7,000 Da was obtained.

### Example 1

13.9 parts by weight of a 1,2-quinonediazide compound (B), 13.3 parts by weight of the epoxy compound (C) of Synthesis Example 2, 75.2 parts by weight of an orthoester, 220.0 parts by weight of the acrylic resin (F) of Synthesis Example 3, and 0.8 part by weight of a surfactant (G) were mixed with 100 parts by weight of the siloxane copolymer (on the basis of the solids content) to prepare a mixture such that the content of the siloxane copolymer (A) of Synthesis Example 1 was 28.7% by weight based on the total weight of the photosensitive resin composition excluding the solvents in a balanced amount. Then, the mixture was added to propylene glycol monomethyl ether acetate (PGMEA) as a solvent (E) such that the solids content thereof was 18.8% by weight, which was dissolved for 3 hours. Then, it was filtered through a membrane filter having a pore diameter of 0.2 μm to obtain a photosensitive resin composition having a solids content of 18.8% by weight. Here, the orthoester was considered as a solvent (orthoester (D)+solvent (E)=81.2% by weight based on the total weight of the photosensitive resin composition) in the calculation of the solids content.

### Examples 2 to 4

Photosensitive resin compositions were each prepared in the same manner as in Example 1, except that the contents of the respective components were changed as shown in Table 1 below.

### Comparative Example 1

A photosensitive resin composition was prepared in the same manner as in Example 1, except that the orthoester (D) was not used.

TABLE 1

| | | Ex. 1 | Ex. 2 | Ex. 3 | Ex. 4 | C. Ex. 1 |
|---|---|---|---|---|---|---|
| Siloxane copolymer (A) | Syn. Ex. 1 | 28.7 | 28.7 | 28.7 | 28.7 | 28.7 |
| 1,2-Quinonediazide | (TPA-517, Miwon) | 13.9 | 13.9 | 13.9 | 13.9 | 13.9 |
| compound (B) | | | | | | |
| Epoxy compound (C) | Syn. Ex. 2 | 13.3 | 13.3 | 13.3 | 13.3 | 13.3 |
| Orthoester (D) | Triethyl | 75.2 | 150.4 | 300.7 | 451.0 | — |
| | orthoformate | | | | | |
| Solvent (E) | Propylene glycol | 77.1 | 73.1 | 65.0 | 56.8 | 81.2 |
| | monomethyl ether | | | | | |
| | acetate | | | | | |
| Acrylic copolymer (F) | Syn. Ex. 3 | 220 | 220 | 220 | 220 | 2.20 |
| Surfactant (G) | FZ-2122, Dow Corning Toray | 0.8 | 0.8 | 0.8 | 0.8 | 0.8 |

### [Test Example 1] Evaluation of Chemical Resistance

The photosensitive resin compositions obtained in the Examples and Comparative Examples were each coated onto a glass substrate using a spin coater and pre-baked at 100° C. for 180 seconds to form a pre-baked film (coated film) having a thickness of 3.0 μm. Thereafter, it was exposed to light (bleaching) at an exposure dose of 0 to 250 mJ/cm² based on a wavelength of 365 nm (insert i-line filter) for a certain time period using an aligner (model name. MA6) that emits light having a wavelength of 200 nm to 450 nm. Next, the pre-baked film was developed for 85 seconds with an aqueous solution of 2.38% by weight of tetramethylammonium hydroxide through puddle nozzles at 23° C. Thereafter, it was exposed to light (bleaching) at an exposure dose of 200 mJ/cm² based on a wavelength of 365 nm for a certain time period using an aligner (model name. MA6) that emits light having a wavelength of 200 nm to 450 nm. Next, the pre-baked film was heated in a convection oven at 240° C. for 20 minutes to prepare a cured film having a thickness of 3.0 μm. Next, the cured film thus prepared was immersed in N-methyl-2-pyrrolidone (NMP) at 40° C. for 10 minutes to evaluate its chemical resistance.

The smaller the change in the thickness of the cured film, the more excellent in chemical resistance. Specifically, when the thickness change of the cured film after immersion relative to the initial thickness of the cured film was 16% or less, it was evaluated as good. When it was greater than 16% to less than 20%, it was evaluated as medium. When it was 20% or more, it was evaluated as bad.

### [Test Example 2] Evaluation of Adhesion

The photosensitive resin compositions prepared in the Examples and the Comparative Examples were each stored at room temperature for 24 hours. Then, the photosensitive resin compositions thus stored were each coated onto a substrate deposited with SiN. using a spin coater and pre-baked at 100° C. for 180 seconds to form a pre-baked film (coated film) having a thickness of 4.5 μm. Next, the pre-baked film was developed for 85 seconds with an aqueous solution of 2.38% by weight of tetramethylammonium hydroxide through puddle nozzles at 23° C. Thereafter, it was exposed to light (bleaching) at an exposure dose of 200 mJ/cm² based on a wavelength of 365 nm for a certain time period using an aligner (model name: MA6) that emits light having a wavelength of 200 nm to 450 nm. Next, the pre-baked film thus exposed was heated in a convection oven at 240° C. for 20 minutes to prepare a cured film having a thickness of 3.0 μm. Then, the cured film thus obtained was cross-cut and stored in an oven at 85° C. and 85% humidity. An adhesive strength test tape was placed on the grid pattern in parallel and attached thereto. It was detached evenly within 0.5 to 1 second at an angle of 180 degrees within 90 seconds. Thereafter, the adhesion was evaluated according to the ASTM D3359 method.

The smaller the differences before and after the tape attachment and detachment of the cross-cut cured film, the more excellent the adhesion. Specifically, when no part was detached from the cross-cut cured film (5B), it was evaluated as good. When 5% or less was detached (4B), it was evaluated as medium. When 15% or more was detached (3B), it was evaluated as bad.

The results of Test Examples 1 and 2 are shown in Table 2 below.

TABLE 2

| | Ex. 1 | Ex. 2 | Ex. 3 | Ex. 4 | C. Ex. 1 |
|---|---|---|---|---|---|
| Chemical resistance | Medium | Medium | Good | Good | Bad |
| Adhesion | Medium | Medium | Good | Good | Bad |

Referring to Table 2, in Examples 1 to 4, falling within the scope of the present invention, in which the orthoester was used, the chemical resistance and adhesion of the cured films were excellent. In contrast, in Comparative Example 1 in which the orthoester was not used, the chemical resistance and adhesion of the cured film were significantly deteriorated.

In addition, excellent adhesion and chemical resistance of the cured film are attributable to the high storage stability of the photosensitive resin composition. Referring to the results of Table 2, the photosensitive resin compositions of Examples 1 to 4 were excellent in chemical resistance and adhesion of the cured films as compared with Comparative Example 1, indicating that they were excellent in storage stability as well.

1. A positive-type photosensitive resin composition, which comprises:
(A) a siloxane copolymer;
(B) a 1,2-quinonediazide compound;
(C) an epoxy compound;
(D) an orthoester; and
(E) a solvent.

2. The positive-type photosensitive resin composition of claim 1, wherein the orthoester (D) is a compound represented by the following Formula 1: 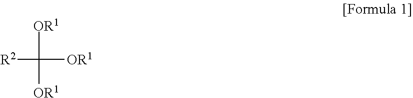
in Formula 1,
R¹ is each independently a substituted or unsubstituted C₁₋₁₀ alkyl group, and
R² is hydrogen or a substituted or unsubstituted C₁₋₁₀ alkyl group.

3. The positive-type photosensitive resin composition of claim 1, wherein the content of the orthoester (D) is 1 to 800 parts by weight relative to 100 parts by weight of the siloxane copolymer (A) on the basis of solids content.

4. The positive-type photosensitive resin composition of claim 1, wherein the siloxane copolymer (A) comprises a structural unit derived from two or more silane compounds represented by the following Formula 2:
(R³)ₙSi(OR⁴)₄₋ₙ [Formula 2]
in Formula 2,
n is an integer of 0 to 3,
R³ is each independently C₁₋₁₂ alkyl, C₂₋₁₀ alkenyl, C₆₋₁₅ aryl, 3- to 12-membered heteroalkyl, 4- to 10-membered heteroalkenyl, or 6- to 15-membered heteroaryl,
R⁴ is each independently hydrogen, C₁₋₆ alkyl, C₂₋₆ acyl, or C₆₋₁₅ aryl, and
the heteroalkyl, the heteroalkenyl, and the heteroaryl groups each independently have at least one heteroatom selected from the group consisting of O, N, and S.

5. The positive-type photosensitive resin composition of claim 1, which further comprises (F) an acrylic copolymer.

6. The positive-type photosensitive resin composition of claim 5, wherein the acrylic copolymer (F) comprises (F-1) a structural unit derived from an ethylenically unsaturated carboxylic acid, an ethylenically unsaturated carboxylic anhydride, or a combination thereof; (F-2) a structural unit derived from an unsaturated compound containing an epoxy group; and (F-3) a structural unit derived from an ethylenically unsaturated compound different from the structural units (F-1) and (F-2).

7. A cured film prepared from the positive-type photosensitive resin composition of claim 1.
